(19) United States
(12) Patent Application Publication
(10) Pub. No.: US 2006/0041397 A1
(43) Pub. Date: Feb. 23, 2006

(54) Method for checking a integrated circuit for electrostatic discharge bobustness

(75) Inventors: Wolfgang Kemper, Pfaffhausen/Zurich (CH); Zeljko Mrcarica, Zurich (CH); Thomas Keller, Tann (CH); Daniel Thommen, Zurich (CH); Joachim Christian Reiner, Kilchberg (CH)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/526,590

(22) PCT Filed: Aug. 25, 2003
(86) PCT No.: PCT/IB03/03787

§ 371 Date: Aug. 1, 2005

(30) Foreign Application Priority Data
Sep. 5, 2002 (EP) 021023114

(51) Int. Cl. G01R 27/28

(52) U.S. Cl. 702/117

(57) ABSTRACT

The invention is a method and a computer program product for checking an integrated circuit for electrostatic discharge (ESD) robustness at the design level and comprises essentially the check of the layout of the integrated circuit against a set of rules defining one or more transistor geometric and/or electrical and/or material values and generating an output or report of this check. This method can check automatically a complete IC design layout at any design level. An exemplary design is an ESD protection layout, a design block or a complete IC design.

The invention relates to a method and a computer program product for checking an integrated circuit for electrostatic discharge robustness in the design phase to avoid expensive redesigns.

Integrated circuits, especially sensitive circuits in complementary metal oxide semiconductor (CMOS) technology, have to be protected against defects which can be caused by electrostatic discharge (ESD). An ESD can have the consequence of a voltage break through a dielectric between two surfaces, in the end this is a short circuit. This can damage the gate oxide/diffusion the metal layers or the contacts of the integrated circuit. The electrostatic charge existing prior to the sudden discharge of the circuit usually results from contact with an electrostatically charged object, e.g. a person or a machine.

For the protection from ESD, specially designed circuits are usually integrated on the substrate of the circuit that has to be protected. The protection circuit is activated when dangerous current or voltage discharges occur and gets into a low-impedance state to keep the sensitive areas of the circuit protected.

The large capital investment required for and the difficulty of reworking and replacing integrated circuit devices which fail in the field because of ESD or electrical overstress have emphasized the need for automated methods of checking integrated circuit layouts with regard to robustness against ESD and electrical overstress (EOS).

In Bass et al. U.S. Pat. No. 6,086,627, a method of automated ESD protection level verification is described. The design is verified by first identifying the chip pads, I/O cells and ESD protect devices. Connections between these structures are checked. Wires between the ESD protect devices and the chip pads and I/O cells are shrunk such that unsuitable connections become disconnected and are found in subsequent checking. Finally, connections to guard rings are checked. Power rails are checked in a similar manner. The metal wires are verified whether they are wider than a minimum width and the resistance from vias is checked whether it does not exceed a maximum tolerable resistance. Physical spaces between design levels are checked and the diode area is compared to a power-to-failure unit area. The program also checks the widths of the supply and ground lines. But a lot of failures, especially the defect of buffer transistors occurring by ESD or critical spacing between diffusions, are not detected over the whole chip area. Since ESD damages can occur not only in the protections, but also outside the protection area, it is uncertain whether a redesign because of ESD failures can be avoided.

The general intention of this invention is to develop and design an ESD check tool for CMOS Circuit blocks that is CMOS generic such that it will work with all CMOS processes.

The focus of this tool is to check the active circuitry before the new chip design is completed, thus minimizing the risk of ESD failures of new chip designs. In detail, the tool is intended to highlight critical layout, i.e. critical spots in the design, and does not address or propose an improvement or redesign. In other words, all structures will be checked.

Though ESD-proofed components will be combined or connected, an ESD problem may still occur because the proofed components have been checked only one by one and not in the system in which they work together.

Thus, an object of the invention is to provide a method and a computer program product for checking an integrated circuit for electrostatic discharge robustness to minimize the risk of ESD failures of the whole layout.

A further and special object of the method according to the invention is to include a check of the layout of transistors in the circuit.

The problem is solved by a method for checking an integrated circuit for electrostatic discharge robustness with the features according to the method claims.

Essentially, the method for checking an integrated circuit for electrostatic discharge robustness according to the invention comprises the following steps:

1. Identify the pads in the layout of the integrated circuit.

2. Identify for each pad the diffusions connected to the pad.

3. Check for each diffusion connected to the pad whether a minimum spacing between the diffusion connected to the pad and a neighboring diffusion is fulfilled.

4. If it is not fulfilled, generate an output, in particular a report.

5. Repeat the steps 3 and 4 above for all identified diffusions.

The computer program product according to the invention is loadable into the internal memory of a computer and comprises software code portions for performing the steps of the above mentioned method for checking an integrated circuit for electrostatic discharge robustness when said product is run on a computer.

The computer program product according to the invention stored on a computer usable medium, comprises computer readable program means for causing a computer to identify a pad in the layout of said integrated circuit, computer readable program means for causing the computer to identify for said pad any diffusions connected to said pad, computer readable program means for causing the computer to check for said diffusion whether a minimum spacing between said diffusion and a neighboring diffusion is fulfilled, computer readable program means for causing the computer to generate an output or report, in particular if the result of said checking is negative, and computer readable program means for causing the computer to check for other identified diffusions whether said minimum spacing is fulfilled and to generate an output or report, in particular if the result of said checking is negative.

The method according to the invention can comprise the following further steps:

1. For each pad the hot nodes connected to the pad will be identified.

2. From the layout the width and length of a metal connection connecting the pad to the hot node will be extracted.

3. From the width, length and process specific values a ESD voltage will be calculated.

4. It will be checked whether the calculated ESD voltage is bigger than a minimum ESD voltage.

5. If it is not bigger than the minimum ESD voltage, an output will be generated.

6. The further steps 2 to 5 above will be repeated for those metal connections which connect the identified hot nodes to the pads.

The ESD voltage for the given structure VESD′ is
VESD′=jfail*W*R−VH
in which jfail is the current density in case of failure, W is the transistor width, R is the serial resistance calculated from the specific resistance, the width and the length and VH is the holding voltage.

In another embodiment of the invention, it will be checked in addition whether predetermined electrical values or predetermined material properties are observed.

In a further embodiment of the invention, process specific values and configurations which are necessary for the check will be stored in and taken from a technology file or will be available to the checker in any other form.

Advantageously the value for the minimum spacing between two diffusions, the minimum ESD voltage, the current density in case of failure, the transistor width, the specific resistance, and the holding voltage will be taken from the technology file.

In a still further embodiment of the invention, the observation of a first design rule in the circuit to be checked is determined. This rule defines that the ratio between the width of all transistors of a first type and the width of a transistor of a second type of a buffer circuit should be smaller than a predetermined value.

In an another embodiment of the invention, the observation of a second rule in the circuit to be checked is determined. According to this rule, a transistor is searched which is connected to two power supplies and it is checked whether the condition VESD<jfail*W*R−VH is fulfilled. VESD is the maximum allowed ESD voltage, jfail is the current density in case of failure, W is the transistor width, R is the serial resistance and VH is the holding voltage.

In a further embodiment of the invention, the observation of a third rule in the circuit to be checked is determined. This third rule determines that there should be no low impedance connection of a transistor gate to a power line or power pad.

In a still further embodiment of the invention, the observation of a fourth design rule in the circuit to be checked is determined. According to this forth rule, a search is made for diffusions of a type which are connected to a hot node and it is checked whether a minimum spacing between two diffusions of this type is kept.

As apparent from the claims, there are a number of further embodiments of the invention, wherein the observation of a number of further rules is determined.

According to a fifth rule, a check for maximum current densities through the paths which lead to a supply/power pad is made. Further, current densities are checked whether they are smaller than the worst case ESD current flowing into a circuit block.

Also, a “no check area layer” (ok—layer) of the integrated circuit can be marked to avoid the check of this chip area.

According to a sixth rule, the design is investigated whether there are any 90° corners in ESD-critical areas of the chip. Also, a corner may be detected, when a non-straight polygon edge is found.

According to a seventh rule, the spacing of the connections of transistors in the integrated circuit is investigated concerning to ESD critical design.

According to an eighth rule, it is investigated whether a predetermined minimum spacing between a contact and a layer is kept.

Finally, according to a ninth rule, it will be checked whether the contacts of a contact array of a transistor are placed in a proper way.

The method checks the whole design with ESD relevant rules, independent whether it is a protection device by definition or not.

Subsequently, the invention is further explained with the drawings. The figures display a number of circuit diagrams to be checked, in particular shows:

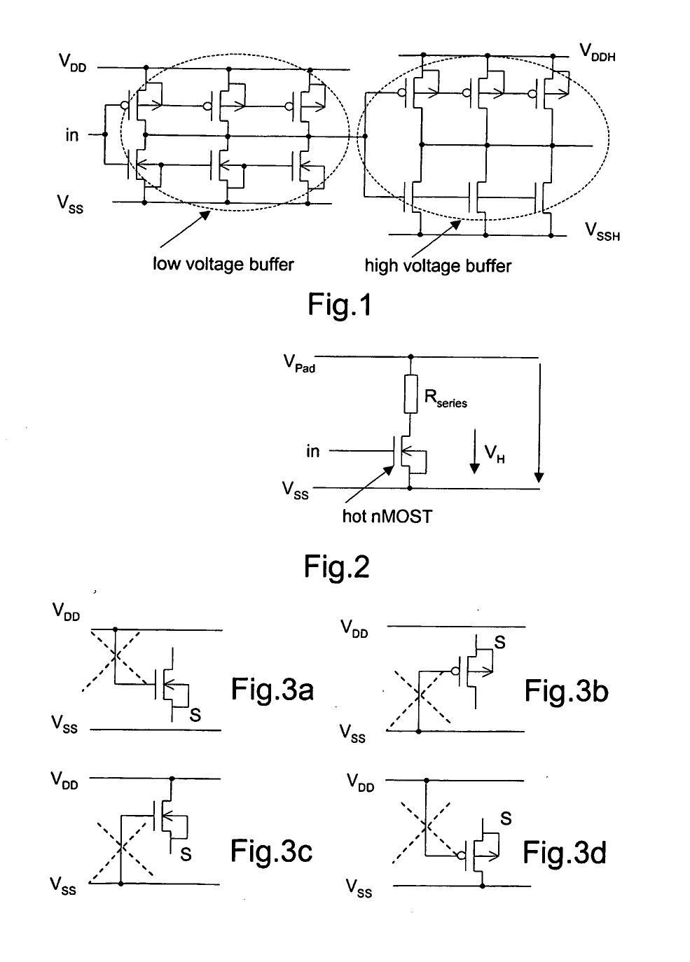

FIG. 1 a circuit diagram with voltage buffers connected to two hot nodes;

FIG. 2 a circuit diagram with a n-MOS transistor connected to two hot nodes;

FIG. 3a a circuit diagram with a n-MOS transistor whose gate is connected to VDD;

FIG. 3b a circuit diagram with a p-MOS transistor whose gate is connected to VSS;

FIG. 3c a circuit diagram with a n-MOS transistor whose gate is connected to VSS;

FIG. 3d a circuit diagram with a p-MOS transistor whose gate is connected to VDD;

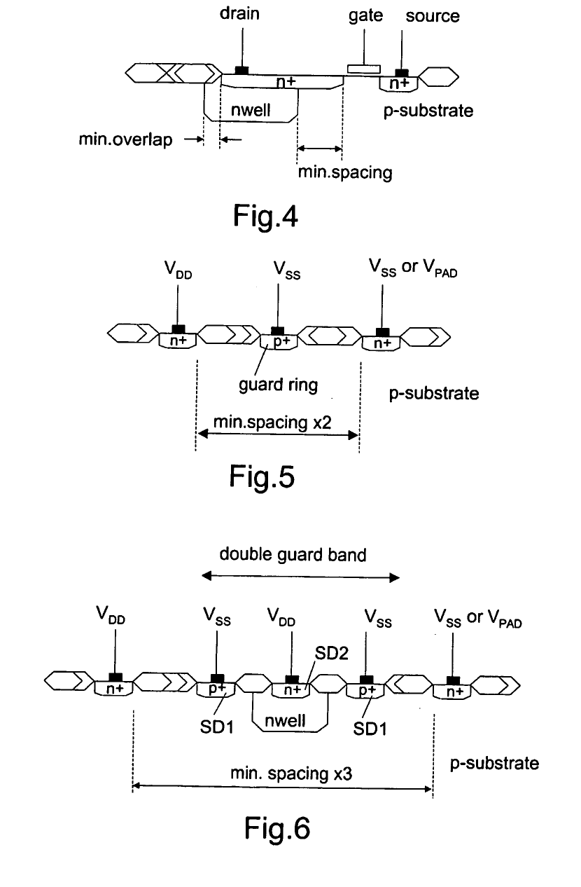

FIG. 4 the structure of a MOS transistor without a guard band;

FIG. 5 the structure of a MOS transistor with a single guard band;

FIG. 6 the structure of a MOS transistor with a double guard band;

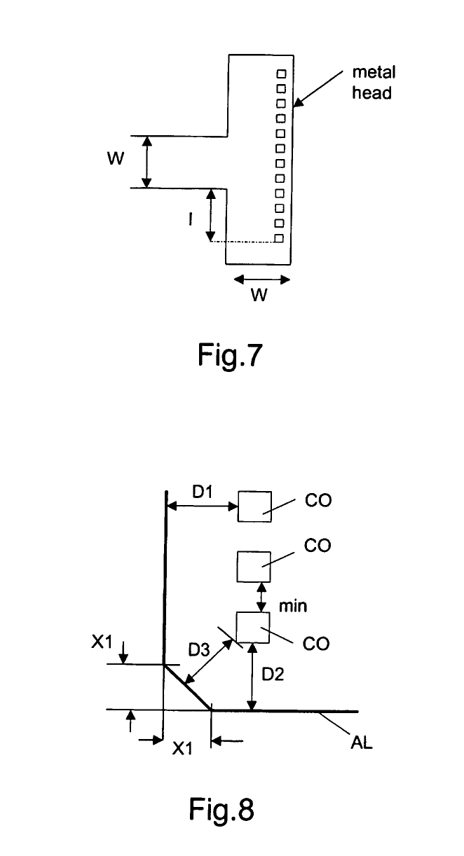

FIG. 7 a layout of a metal connection of current carrying diffusions of a transistor;

FIG. 8 a layout of contacts;

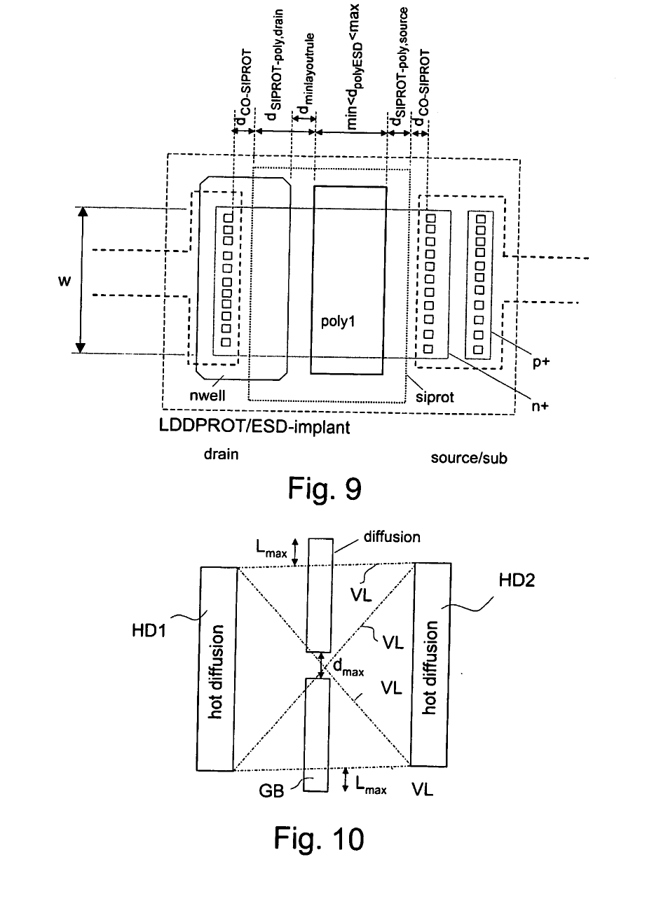

FIG. 9 a layout of a ESD-transistor;

FIG. 10 a schematic depiction of a guard band;

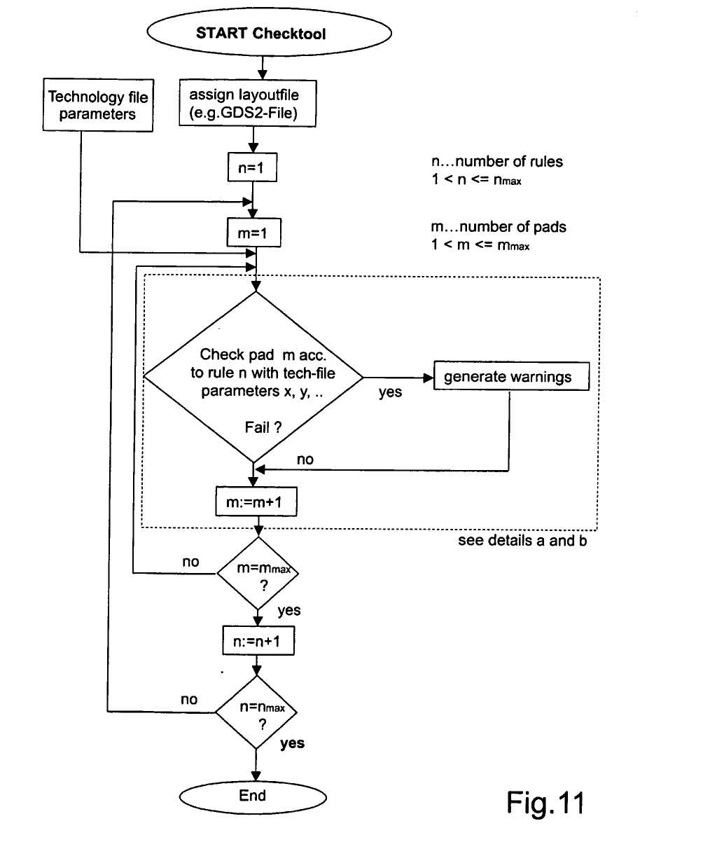

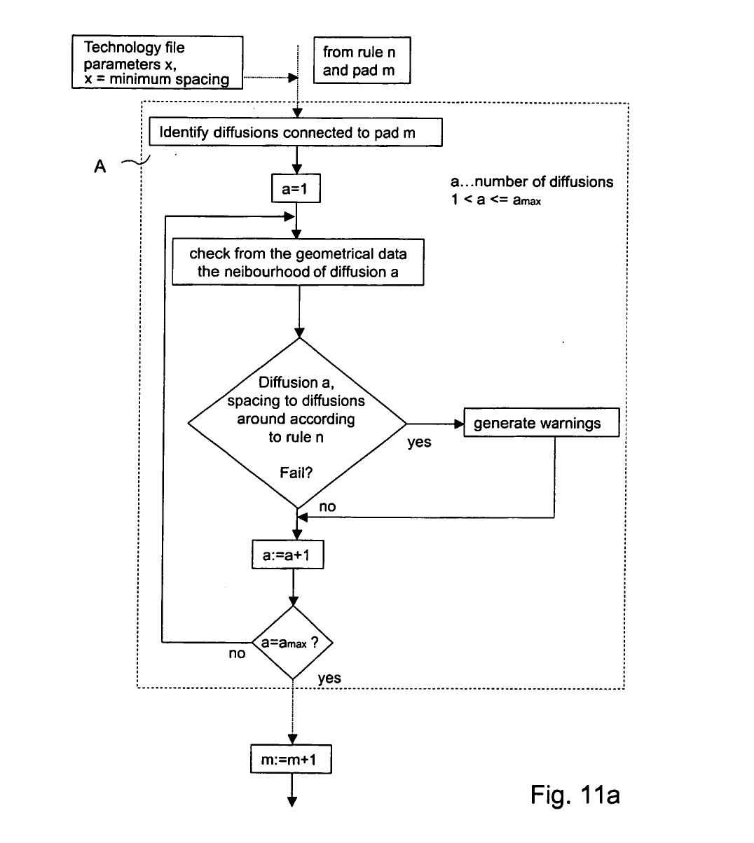

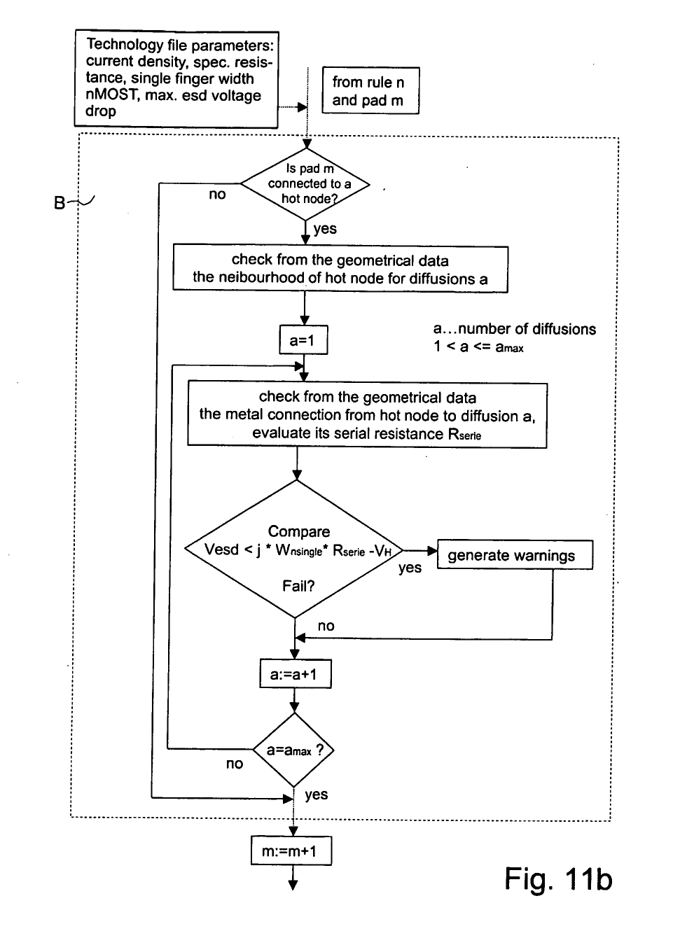

FIG. 11a a simplified flow diagram of the method according to the invention;

FIG. 11a a part of the flow diagram of the method according to the invention, which is shown in FIG. 11, in detail with a first check rule;

FIG. 11b a part of the flow diagram of the method according to the invention, which is shown in FIG. 11, in detail with a second check rule;

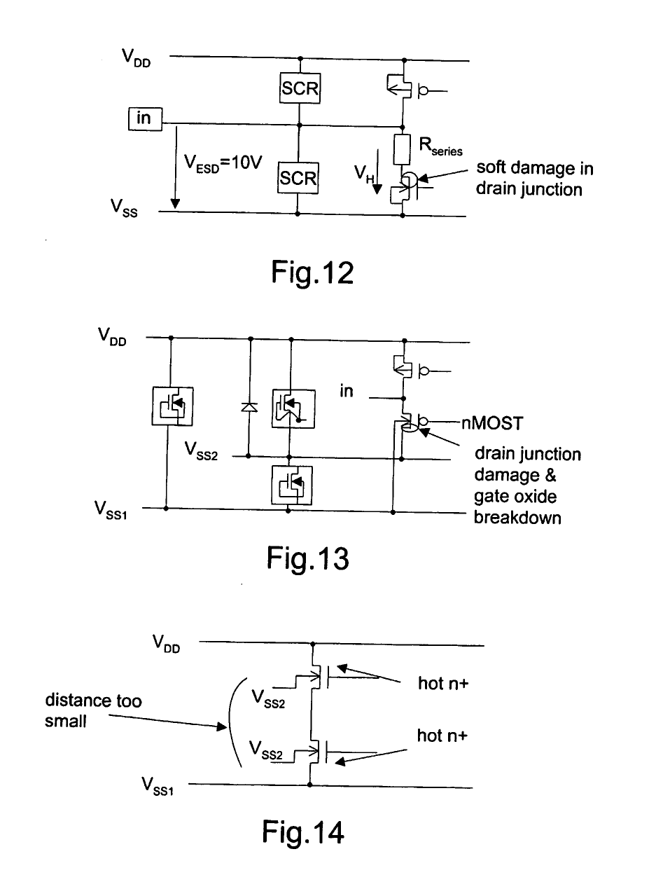

FIG. 12 a circuit diagram with a first design failure which will be detected by the method according to the invention;

FIG. 13 a circuit diagram with a second design failure which will be detected by the method according to the invention;

FIG. 14 a circuit diagram with a third design failure which will be detected by the method according to the invention;

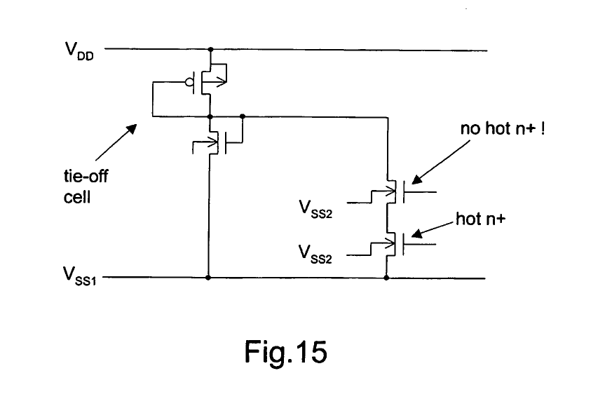

FIG. 15 a circuit diagram with a forth design failure which will be detected by the method according to the invention.

The method for checking an integrated circuit for electrostatic discharge robustness according to the invention checks the layout of the integrated circuit with one or more rules whether one or more transistor specific geometric values are kept. If they are not kept, a report will be generated.

Several classes of hot nodes have to be distinguished, as different power supplies and different kind of input, output and IO pads. In the following the expression hot node will be used uniform. If a distinction is necessary it will be done at the appropriate place.

For each pair of hot nodes, the ESD voltage VESD that may occur between them during ESD stress has to be determined and given as input into a technology file. This parameter VESD results from the ESD protection network concept. The technology file-parameters VESD are circuit-specific.

In the following the rules will be described which can by used by the method according to the invention. In the method some or all the rules described below can be used.

Buffer Rule

A buffer as shown in FIG. 1 is any series arrangement of p-channel metal oxide semiconductor transistors (pMOSTs) and n-channel metal oxide semiconductor transistors (nMOSTs) between any pair of hot nodes. Hot nodes in FIG. 1 are indicated with VDD, VSS, VDDH and VSSH.

Depending on the process parameters, the protection concept and the kind of hot node involved, a critical buffer number bcrit is determined and introduced into the technology file. The tool extracts from the figure the values W_{P}^{tot}, Wₙ^{sin gle}, L_{N}^{min} and L_{N} and calculates a buffer value b:

$$b = \frac{{W}_{p}^{tot}}{{W}_{N}^{single}} \cdot \frac{{L}_{N}^{min}}{{L}_{N}}$$

wherein
W_{P}^{tot}=total p-channel transistor width
Wₙ^{sin gle}=width of the shortest finger of the n-channel transistor
L_{N}^{min}=n-channel transistor minimum length (process dependent)
L_{N}=n-channel transistor length

It will be checked whether the buffer value b is smaller than the critical buffer number bcrit. If this is not the case, a failure massage will be created.

As well as low voltage buffers and high voltage buffers can be checked by the method or tool according to the invention.

Rule for Hot nMOSTs

A hot nMOST is an nMOST connecting two hot nodes. This is shown in FIG. 2. A rule can be implemented in the check tool to determine whether the n-channel MOS transistor is sufficiently protected or not.

Depending on the fulfillment of process-specific ESD-layout rules for example spacing, good metal connection, etc., two different failure current densities jfail_std and jfail-ESD apply will be specified in the technology file. The current densities are usually given in mA/μm.

The tool checks whether the condition
V_{ESD}<j_{fail}·W_{N}^{sin gle}·Rₛₑᵣᵢₑₛ−V_{H}
wherein
Rₛₑᵣᵢₑₛ=serial resistance
V_{H}=holding voltage
is fulfilled.

jfail_std and jfail_esd are two values for jfail which characterize two current levels in which the transistor can be and are used for the check.

Rule for Hot pMOSTs

The rule for hot pMOSTs is similar to the rule for hot nMOSTs, which is described above.

Rule for Gates

There should not be any hard connection of a gate to a power line or pad as shown in the FIGS. 3a, 3b, 3c and 3d. Therefore a connection of the gate of a n-channel MOS transistor to VDD as shown in FIG. 3a and a connection of the gate of a p-channel MOS transistor to VSS as shown in FIG. 3b is not allowed. Also a connection of the gate of a n-channel MOS transistor to VSS, when at the same time the drain of the same transistor is connected to VDD as shown in FIG. 3c and a connection of the gate of a p-channel MOS transistor to VDD, when at the same time the drain of the same transistor is connected to VSS as shown in FIG. 3d is not allowed.

The serial resistance Rseries for example has to be bigger than 5 kOhm. The tool checks whether the above mentioned forbidden configurations occur.

Rules for Hot n+Diffusions

Hot n-diffusions are n-diffusions connected to a hot node as shown in FIG. 4. The tool checks the following items:

1. Hot n+diffusion:

The voltage ΔVhot should be smaller than the voltage VBD of the diffusion junction breakdown voltage VBD_n+ specified in the technology file where
ΔVhot=Vhot_upper−Vhot_lower
and where
Vhot_upper is the highest potential and
Vhot_lower is the lowest potential.

In case the diffusion forms a drain of a transistor in a power domain, the voltage VBD_n+drain applies which is the minimum of the different drain junction breakdown voltage values or the gate oxide breakdown value given in the specification.

2. The spacing of two hot n+diffusions connected to different hot nodes should be bigger than a first minimum spacing value X1.

3. If a single guard band between hot n+diffusions connected to different hot nodes exists, a modified spacing rule applies. It will be checked whether the n+/n+diffusion spacing is bigger than a second minimum spacing X2.

4. If a double guard band between hot n+diffusions connected to different hot nodes exists, a further modified spacing rule applies. It will be checked whether the n+/n+diffusion spacing is bigger than a third minimum spacing X3.

5. Place a n+well under the n+diffusion if this is available in the process.

The tool or method can recognize a single guard band as shown in FIG. 5 and double guard band as shown in FIG. 6. Both will be described below. The method recognizes both in order to check the above-mentioned rules.

A single guard band or guard ring is defined as a stripe of diffusion with doping polarity of the substrate connected to the supply voltage of the substrate e.g. VSS.

A double guard band is defined as a stripe of diffusion SD1 with doping polarity of the substrate connected to the supply voltage of the substrate e.g. VSS and a parallel stripe of diffusion SD2 of opposite polarity of the substrate connected to the maximum supply of opposite polarity than that connected to the substrate used in the block.

Rules for Hot p+Diffusions

The rules for hot p+diffusions are similar to the rules for hot n+diffusions, which are described above. The method according to the invention works therefore appropriately.

Rules for Current Densities

ESD current paths must not exceed specified current density limits that have to be specified in the technology file. The list of parameters to be specified comprises:
jmi=current density in metal layer i
ICO=current per contact hole
IVIAi=current per via i

This check consists of two steps. First, the worst case ESD current IESD flowing into a circuit block is determined. Second, all paths of the ESD currents IESD have to be followed to the supply pads. For each section of this path, the sum of all IESD flowing through it have to be added up and the current density criteria have to be checked.

For the determination of the ESD current IESD, two methods or variants are proposed.
Variant A:
Using the relation:

$${I}_{ESD} = \sum \frac{{V}_{ESD} - {V}_{H}}{{R}_{series}}$$
wherein
VH=the holding voltage of the nMOSTs in snap-back
Rseries=the resistance in series with the nMOST.

In the typical case that a p-channel MOS transistor is in series with the n-channel MOS transistor, Rseries can be determined as:

$${R}_{series} = \frac{{V}_{ESD} - {V}_{H}}{{I}_{pMOST} ( {V}_{D} = {V}_{ESD} - {V}_{H} ; {V}_{G} = {V}_{ESD} )}$$

wherein
VD=drain voltage
VG=gate voltage

The ESD current IESD will be determined using the transistor model for worst case parameters, which means minimum sheet resistances and fast transistor parameters.

A second method avoiding to involve the use of the transistor models is

Variant B:

Assuming all nMOSTs are in snap-back and carry a current density limit of failure jfail.

$${I}_{ESD} = {j}_{fail} \cdot {\sum }_{all nMost fingers} {W}_{N}$$

This is of course a worst case estimate. It needs to be checked on some typical examples how large the difference of the two methods is before it can be decided which method needs to be implemented.

“ok-layer” Option

In order to be able to handle difficult unforeseen situations, the tool can provide a “ok-layer” option telling the check tool not to check certain areas. This “ok-layer” will be placed onto the layout after manual check by an ESD-expert. It disappears automatically as soon as the layout is touched.

With this optional “ok-layer” certain chip areas or structures can be hidden.

Polygon Corners Under Metal

In the technology file can be specified whether 90° corners of polygon silicon lines are allowed under the hot metal layer 1.

Metal Connection of Current Carrying Diffusions

Metal connections of transistors as shown in FIG. 7 must be wide enough to avoid voltage drops exceeding a certain voltage limit ΔVcrit. This value is stored in the technology file as parameter.

The tool checks if

$$Δ V = {I}_{max} \cdot R = {j}_{fail , max} \cdot {R}_{sq , max} \cdot \frac{{d}_{head}^{2}}{{W}_{head}} < Δ {V}_{cri}$$

wherein
W_{head}=width of resistor head
R_{sq,max}=resistance per square
d_{head}=length of resistor head

Round Corners of Hot Diffusions

A round corner is shown in FIG. 8. An active line AL runs along contacts CO. The process-critical minimum dimensions D1, D2 and D3 are specified by the technology file parameters. D1 is the exact first distance from the left side of the contact CO to the active line AL, D2 is the exact second distance from the edge of the contact CO to the active line AL and D3 is the exact third distance from lower side of the contact CO to the active line AL. The minimum distance min is the minimum distance between two contacts CO.

In FIG. 8, X1 is the minimum spacing of a layer to a neighboring layer of the same kind, for example a minimum n+/n+diffusion spacing.

With the method according to the invention it can be checked if:
the dimension D1 is bigger than the minimum dimension D1, for example=2*D1 (minimum layout rule);
The minimum dimension D1 is given by the process.
the dimension d2 is bigger than the minimum dimension D2 and if D2 is bigger than the minimum dimension D1, for example=3*D2 (minimum layout rule);
The minimum dimension D2 is given by the process.
the dimension d3 is bigger than the minimum dimension D3 and D3 is bigger than the minimum dimension D1, for example=3*D3 (minimum layout rule).
The minimum dimension D3 is given by the process.

ESD Transistor Layout

Contact arrays as shown in FIG. 9 on current carrying diffusions must have a minimum contact-contact spacing, be placed face-to-face to their counterpart to allow a optimal current flow, and obey the other spacing rules for ESD-transistors. Further ESD-spacing rules are illustrated in the following.
1. distance SIPROT to drain contact=minimum Design rule
2. overlapp SIPROT over diffusion=process dependent
3. spacing between diffusion and gate=process dependent
4. gate length=process dependent
5. overlapp SIPROT over gate=process dependent
6. distance SIPROT to source contact=minimum Design rule

Donut Structures

A donut structure is a ring shaped protection structure. Unless a method will be found to treat donut shaped structures (as ESD protection devices) is a suitable manner, such structures can just be detected by the tool and highlighted. A method to detect a corner is to check for any non-straight polygon edge on active. The ESD expert checks them manually and places an “ok-layer” over it.

ESD Layers

The layers that have to be applied or omitted for ESD-robust devices and the corresponding rules have to be defined in the technology file for the specific process. Such layers are ESD-implant, SIPROT and LDDPROT. The ESD implant is a special implant to increase the ESD robustness. SIPROT means a not silicided region and LDDPROT is a not low doped drain region.

Guard Bands

The following diffusions are considered as guard band for hot n+diffusions. For hot p+diffusions the polarities are inverted.
hot n+diffusion connected to the potential low
single guard band p+diffusion connected to VSS
second guard band n+/n well connected to VDD
hot n+diffusion connected to the potential high

The guard band topology is shown in the FIG. 10. A guard band GB has to cover and even overlap the area defined by all view lines VL between the two hot diffusions HD1 and HD2 which have to be separated. The minimum amount of required overlap Lmax and the allowed maximum size of a gap in the guard band dmax have to be specified in the technology file.

In FIG. 11, the flow diagram of the method according to the invention is shown. At the beginning the layout file, for example a GDS2 file, will be assigned to the check tool. The counter for the number of rules n will be set to 1 and the counter for the number of pads will also be set to 1. The value nmax delivers the maximum number of rules, while the value mmax delivers the maximum number of pads. Now it will be checked if the first rule for the pad number m=1 is fulfilled. The process specific parameters which are necessary for the check will be taken from the technology file while the geometrical values are extracted from the layout file. If the result of the check shows that the condition is not fulfilled a report, warning or failure massage is created. Next the counter m will be increased and the same procedure will be done for the pad Number m=2. After the last pad has been checked the rule counter n will be increased and it will be checked if the second rule (n=2) is fulfilled and again if the rule is not kept a report will be created. This steps will be repeated as often as all rules have been checked. Which rules are implemented in the rule checker depends on the specific application.

FIG. 11a shows a part of the flow diagram of the method according to the invention, which is shown in FIG. 11, in detail with a first check rule (e.g. rule number n=1) comprising the following steps:

1. Identify for each pad the diffusions connected to the pad. The value amax delivers the number of identified diffusions which are connected to the pad.

2. Check for each diffusion connected to the pad, beginning with the diffusion number a=1, whether a minimum spacing between the diffusion connected to the pad and a neighboring diffusion is fulfilled.

3. If it is not fulfilled, generate an output, in particular a report.

4. Increase the diffusion number a.

5. Repeat the steps 2 to 4 for all identified diffusions till the value amax is reached.

This rule can be used for checking the spacing around a diffusion, e.g. the spacing to a guard band.

FIG. 11b shows a part of the flow diagram of the method according to the invention, which is shown in FIG. 11 as block with a dotted line, in detail with a second check rule, e.g. rule number n=2. Part B is an alternative to the part A from FIG. 11a.

The following steps will be worked off:

1. For the pad with the pad number m the hot nodes connected to this pad will be identified. If there is no hot node the pad number will be increased and for the pad with the pad number m=m+1 the hot nodes connected to this pad will be identified.

2. From the layout file the geometrical data, this means the width and length of a metal connection connecting the pad to the hot node, will be extracted.

3. From the width, length and process specific values, which can be taken from the technology file, the serial resistance Rserie and the ESD voltage will be calculated.

4. Afterwards it will be checked whether the calculated ESD voltage is bigger than a minimum ESD voltage, which is also taken from the technology file.

5. If it is not bigger than the minimum ESD voltage, an output will be generated.

6. The steps 1 to 5 will be repeated for those metal connections which connect the identified hot nodes to the pads.

This rule can be used for checking the ESD robustness of a hot n-MOS transistor.

With the method according to the invention, the following damages can be detected. The list below however serves only for explanation, the invention is not restricted to this examples.

Some layouts of ESD problems are analysed here in order to show how the ESD check rules according to the invention handle them.

### EXAMPLE 1

An analogue circuit buffer failed with damage in the nMOST.

Layout:
6 nMOST fingers; WNsingle=22 μm
12 pMOST fingers; Wptot=408 μm; LN=0.5 μm
LNmin in this process is 0.5 μm

The critical buffer factor for this process bcrit=5

$$buffer number b = \frac{{W}_{p}^{tot}}{{W}_{N}^{single}} \cdot \frac{{L}_{N}^{min}}{{L}_{P}} = \frac{408}{22} \cdot \frac{0 , 5}{0 , 5} = 18 >> bcrit=5$$

This shows that the ESD problem will be found by the method according the invention.

### EXAMPLE 2

Outputs failed by soft drain junction damage depending on the particular I/O-pad-cell shown in FIG. 12.

The parameters V_{H}^{nMOST}=5 V and L_{SIPROT}=5 μm, resulting in
Rseries=6Ω are taken from the technology file.
1. step: ESD-layout ok->jssb=10 mA/μm
2. step: check rule for hot nMOSTs
   V_{ESD}<j_{fail}·W_{N}^{sin gle}·Rₛₑᵣᵢₑₛ−V_{H}
10V<10 mA/μm*44 μm*6 Ω+5V=7.6V

Thus, the rule is not fulfilled.

When adding Rₛₑᵣᵢₑₛ^{min}=14.3 Ω (resulting from layout geometry and minimum specification sheet resistance values for polygon resistor) resulting in Rₛₑᵣᵢₑₛ^{tot}=20.3 Ω:
V_{ESD}<j_{fail}·W_{N}^{single}·Rₛₑᵣᵢₑₛ−V_{H}
10V<10 mA/μm*44 μm*20.3 Ω+5 V=13.9 V
the ESD rules are fulfilled.

### EXAMPLE 3

A failing transistor in the charge pump control circuits of LCD drivers causes a damage and a gate oxide breakdown. The circuit is shown in FIG. 13.

The ESD voltage VESD given by the technology file:
V_{ESD}^{VSS2}=5V
V_{ESD}^{VDD}=15V

Also from the technology file, the following break down voltage parameter VBD can be taken:
V_{BD}^{n+drain}=12V (here the minimum drain junction breakdown has to be taken). It will be checked if ΔVhot<VBD is fulfilled.

Because 10V<12V is true, the rule is fulfilled.

### EXAMPLE 4

The critical buffer structure shown in FIG. 14 failed.

After checking the distance between hot n+diffusions, it can be seen that this distance is too low. The correct parameter for this distance is taken from the technology file.

The ESD problem can be fixed by adding a tie-off cell to avoid head connection of the series-nMOSTs to VDD. Afterwards the drain of upper nMOST is no more a hot diffusion. The tool according to the invention further checks whether the pMOST is sufficiently small to protect the series-nMOSTs (=buffer rule).

The invention can be used as CMOS-generic, automated ESD rule check tool for CMOS processes and derivates, based on layouts of single or multi-metal-layer analog and digital designs. It consists of a check tool with implemented rules to be checked and with a technology-file containing the process-dependent parameters. The latter may be included in the check tool and be adjustable, e.g. via an input screen, for different processes, e.g. CMOS processes and derivates.

The check tool according to the invention is able to check automatically complete IC design layouts at any design level. The design can be an ESD protection layout, a design block or the complete IC design. Also, the metal-metal contact ratio between contact areas and metal width in ESD paths from metal layer to metal layers can be checked. The check tool can highlight all rule violations through warnings or other indications.

1. A method for checking an integrated circuit for electrostatic discharge robustness, comprising:
(a) identifying a pad in the layout of said integrated circuit,
(b) identifying for said pad any diffusions connected to said pad,
(c) checking for each said diffusion whether a minimum spacing between said diffusion and a neighboring diffusion is fulfilled,
(d) generating an output if the result of said checking indicates the minimum spacing between said diffusion and the neighboring diffusion is not fulfilled, and
(e) repeating the steps (c) and (d) for other identified diffusions.

2. The method according to claim 1, further comprising
(a) identifying for the pad any hot nodes connected to said pad,
(b) extracting from the layout the width and length of a conductor connecting said pad to each said identified hot node,
(c) calculating from said conductor's width and length and from process-specific values an ESD voltage,
(d) checking whether said calculated ESD voltage is greater than a predetermined minimum ESD voltage,
(e) generating an output if the result of said checking indicates said calculated ESD voltage is greater than the predetermined minimum ESD voltage, and
(f) repeating the steps (b) to (e) for other conductors connecting identified hot nodes to said pad.

3. The method according to claim 2, wherein the predetermined minimum ESD voltage is selected to be jfail*W*R−VH, wherein jfail is the current density in case of failure, W is the transistor width, R is the serial resistance calculated from the specific resistance, the width and the length, and VH is the holding voltage.

4. The method according to claim 1, further including a check whether the determined values exceed predetermined electrical values or material properties.

5. The method according to claim 1, wherein process specific values and/or properties are taken from a technology file.

6. The method according to claim 5, wherein the value for the minimum spacing between two diffusions, the predetermined minimum ESD voltage, the current density in case of failure, the transistor width, the specific resistance, and the holding voltage are taken from the technology file.

7. The method according to claim 1, further including a check whether the ratio between the width of a transistor of a first type and the width of a transistor of a second type of a circuit is smaller than a predetermined or defined value and, at least if not, generating an output.

8. The method according to claim 1, further including a check for hard connections of gates to power lines or pads and, if found, generating an output.

9. The method according to claim 1, further including a check for diffusions of a predetermined type connected to a hot node and a determined performed whether a minimum spacing between two diffusions of said type is kept.

10. The method according to claim 1, further including a check whether the current densities through paths leading to a supply pad are within predetermined limits.

11. The method according to claim 1, wherein a layer of the integrated circuit can be indicated to avoid the check of said layer.

12. The according to claim 1, further including a check for 90° corners in the structure of the integrated circuit.

13. The method according to claim 12, wherein a corner is identified as a non-straight polygon edge of a predetermined size.

14. The according to claim 1, further including a check whether the spacing of transistor connections fulfills predetermined requirements.

15. The method according to claim 1, further including a check for minimum spacings between a contact and a predetermined layer.

16. A computer program product loadable into the internal memory of a digital computer, comprising software code portions for performing the steps of of claim 1 when said product is run on a computer.

17. A computer program product stored on a computer usable-medium, comprising
computer readable program means for causing a computer to identify a pad in the layout of said integrated circuit,
computer readable program means for causing the computer to identify for said pad any diffusions connected to said pad,
computer readable program means for causing the computer to check for said diffusion whether a minimum spacing between said diffusion and a neighboring diffusion is fulfilled,
computer readable program means for causing the computer to generate an output or report, if the result of said checking indicates the minimum spacing between said diffusion and the neighboring diffusion is not fulfilled, and
computer readable program means for causing the computer to check for other identified diffusions whether said minimum spacing is fulfilled and to generate an output or report, if the result of said indicates the minimum spacing between said diffusion and the neighboring diffusion is not fulfilled.

17. A computer program product stored on a computer usable medium, comprising computer readable program means for performing the steps of claim 1.

18. A computer program product stored on a computer usable medium, comprising computer readable program means for performing the steps of claim 2.

19. A computer program product stored on a computer usable medium, comprising computer readable program means for performing the steps of claim 3.

20. The method according to claim 1, further including a check whether the determined values exceed predetermined electrical values and material properties.
